(19) United States
(12) Patent Application Publication
(10) Pub. No.: US 2005/0086568 A1
(43) Pub. Date: Apr. 21, 2005

(54) System and method of fault detection and recovery in commercial process flow

(76) Inventors: Kenneth Michael Goul, Mesa, AZ (US); Haluk Demirkan, Chandler, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/943,363

(22) Filed: Sep. 17, 2004

Related U.S. Application Data
(60) Provisional application No. 60/504,461, filed on Sep. 18, 2003.
(60) Provisional application No. 60/572,707, filed on May 19, 2004.

(51) Int. Cl. H04L 1/00; G06F 11/00; G06F 11/30; H03M 13/00; G08C 25/00

(52) U.S. Cl. 714/746

(57) ABSTRACT

A commercial processing system has a plurality of processing steps involved in the commercial system defining a product or service. Each of the processing steps has a start point and an endpoint. One or more checkpoints are positioned between the start point and endpoint of the processing steps. Each checkpoint provides a communication to record completion of actions up to the checkpoint. The checkpoint contains status information for the processing step and defines a recordable and recoverable processing point. The checkpoint communication includes a fault recovery field. A computer system stores the checkpoint communications. A communication link is provided between the checkpoints along the processing steps and the computer system. The checkpoints stored in the computer system identifies the completed processing steps to provide recovery information upon detecting an error condition.

### CLAIM TO DOMESTIC PRIORITY

The present non-provisional patent application claims priority to provisional application Ser. No. 60/504,461 entitled “Globally Consistent Checkpointing for Reliability and Fault Tolerance Recovery and Management in Inter-organizational Workflow Systems”, filed on Sep. 18, 2003. The present non-provisional patent application further claims priority to provisional application Ser. No. 60/572,707 entitled “Globally Consistent Checkpointing for Reliability and Fault Tolerance Recovery and Management in Inter-organizational Workflow Systems-Reliable Workflow Systems”, filed on May 19, 2004.

### FIELD OF THE INVENTION

The present invention relates in general to commercial processing systems and, more particularly, to a system and method of fault detection and recovery in a commercial process flow.

### BACKGROUND OF THE INVENTION

Most if not all commercial systems involve a series of processing steps performed by one or more organizations or providers operating within the stream of commerce. The series of processing steps take raw materials or base components through various manufacturing steps to realize an end product. In the context of goods, one provider manufactures goods from raw materials and provides its end product to another provider who in turn uses the product, typically in combination with products acquired from other providers to manufacture its own end product. Within one provider, materials flow from one step to the next step until the end product of the provider is realized. The process continues adding levels of manufacturing hierarchy until the final product is made available to the end consumer. Services may follow a similar pattern.

Consider the example of a home builder. One organization or provider manufactures lumber from raw materials; another provider manufactures nails; another provider manufactures concrete for the foundation; another provider builds cabinets; another provider manufactures bathroom fixtures; and yet another provider produces carpeting. Each of these providers follow a process flow comprising multiple steps in manufacturing its end product. In the case of lumber, timber is harvested from forests, and transported to a sawmill. The bark is removed and the logs are sawed into various cross-sectional areas and lengths. In the case of nails, raw metal is heated into a molten state and poured into forms. The home builder combines each of the above goods and services in a multi-step, timing-critical process flow to yield a quality housing structure within budget for the consumer. Similar multi-tiered manufacturing process flows can be found in durable goods, high-tech manufacturing, retail business, services industry, and many other streams of commerce.

Organizations involved in multi-tiered commercial process flows are well aware of the problems that can arise if a defect occurs anywhere in the process. If the concrete mix is not per specification, the foundation may crack. If the lumber arrives in a warped or green condition, the framing may be delayed. If the cabinets don't fit, they must be re-worked. If the carpet is the wrong color, it must be sent back.

Some problems are not detected or corrected for a considerable amount of time because the failure event itself may be undetected. In other cases, the optimal rework solution is unknown because the error may have occurred far upstream in the commercial flow. The process flow of the organization which created the defect is unknown to the organization that detected the defect. The question of who has responsibility to perform the rework and how it should be done cannot be easily answered. Such latent defects reduce consumer confidence and weigh heavily on manufacturer's reputations.

Similar scenarios can be found in many other manufacturing and commercial process flows. If a step in the process flow is missed, defective, or incomplete, the remaining downstream process steps can be adversely effected. The end product may contain defects which can proliferate and cause problems in other process flows. Even if the problem is detected, there may be insufficient information to determine the most effective rework process, often because information is not shared between different organizations and levels of the multi-tiered commercial process flow.

A need exists for detecting anomalies in commercial process flows and provide corrective action before the defect affects other systems.

### SUMMARY OF THE INVENTION

In one embodiment, the present invention is a commercial system having fault detection and recovery capability comprising a plurality of processing steps involved in the commercial system. One or more checkpoints are positioned within the plurality of processing steps. Each checkpoint provides communications to record completion of actions taken up to the checkpoint. A computer system stores the communications from the checkpoints. A communication link is provided between the checkpoints along the plurality of processing steps and the computer system. The communications provide recovery information upon detecting an error condition.

In another embodiment, the present invention is a method of fault detection and recovery in a commercial system comprising providing a plurality of processing steps involved in the commercial system, providing a checkpoint within the plurality of processing steps, wherein the checkpoint provides a communication to record completion of actions taken up to the checkpoint, and recording the communication to provide recovery information upon detecting an error condition.

In another embodiment, the present invention is a method of recovering a commercial process flow comprising providing a processing step involved in the commercial process flow, providing a checkpoint within the processing step of the commercial process flow, and recording a communication from the checkpoint for providing recovery information upon detecting an error condition.

### BRIEF DESCRIPTION OF THE DRAWINGS

FIG. 1 illustrates a commercial process flow of a product;

FIG. 2 illustrates a commercial process flow of a system;

FIG. 3 illustrates a commercial process flow of a service;

FIG. 4 illustrates a commercial process flow with branches;

FIG. 5 illustrates a commercial process flow involving multiple providers;

FIG. 6 illustrates a commercial process flow involving multiple services;

FIG. 7 illustrates a checkpoint between start and end points of a process step;

FIG. 8 illustrates a checkpoint communication format;

FIG. 9 illustrates a process of detecting a failure and initiating recovery procedure based on checkpoint;

FIG. 10 illustrates a computer system interfacing the commercial process flow; and

FIG. 11 illustrates the steps of fault detection and recovery in a commercial system.

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Commercial systems often involve a series of process steps performed by one or more organizations or providers in the stream of commerce. The series of process steps take raw materials or base components through various manufacturing steps to realize an end product. Most products and services are part of multi-tiered manufacturing process, i.e., one provider's end product is another provider's raw material. Such commercial systems are interrelated in that faults and defects in one process flow can cause problems in another process flow.

The following discussion applies to many different product and service providers and associated process flows. For example, multi-tiered manufacturing process flows can be found in durable goods, high-tech manufacturing, retail business, banks, supply chain networks, insurance companies, healthcare organizations, services industry, and many other commercial environments.

In general, one organization manufactures goods from raw materials and provides its end product to another organization who in turn uses the product, typically in combination with products from other providers to manufacture its own end product. Within one organization, materials flow from one step to the next step until the end product of the. organization is realized. The process continues adding levels of manufacturing hierarchy until the final product is made available to the end consumer. In most cases, the process and sequence of events are relatively constant and do not dynamically change. The majority of multi-organizational tasks, the responsibilities, and the courses of action to be taken by each organizational participant are set by contract and course of performance. Services may follow a similar pattern.

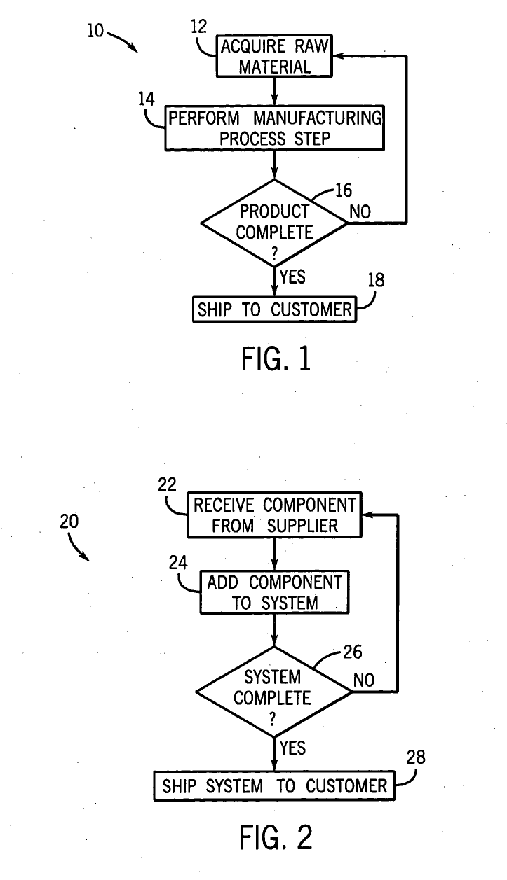

Consider commercial process flow 10 as shown in FIG. 1. A manufacturer or provider of goods acquires raw material from its supplier in step 12. In step 14, the provider performs manufacturing steps on the raw material to form a portion of the product. In the semiconductor industry, the provider may receive blank silicon wafers from its supplier. The provider performs initial processing steps on the silicon wafers. The processing steps may involve one or more assembly steps or actions such as cleaning and pre-formation steps. If the product is not complete in step 16, the provider returns to step 12 to get additional raw materials, e.g., chemical processing agents and materials. The additional raw materials are added to the developing product in step 14 again, and the completion state of the product is checked again in step 16. If the product is not complete, the flow returns to step 12 and the cycle repeats. Once the product is finished, the end product is sent to the customer in step 18. In this case, the end product may be an integrated circuit (IC) chip.

In FIG. 2, a higher level commercial process flow 20 is shown. The manufacturer or provider of goods receives components from its suppliers in step 22. In step 24, the provider assembles the components toward completion of a system. In the electronics industry, the provider receives ICs from its supplier and places the ICs on a circuit board as part of a larger system, e.g., cell phone or computer. Again, the processing steps may involve one or more assembly steps or actions. If the system is not complete in step 26, the provider returns to step 22 to get additional components. The additional components are added to the developing system in step 24, and the completion state of the system is checked again in step 26. If the product is not complete, the flow returns to step 22 and the cycle repeats. Once the system is finished, the end product is sent to the customer in step 28.

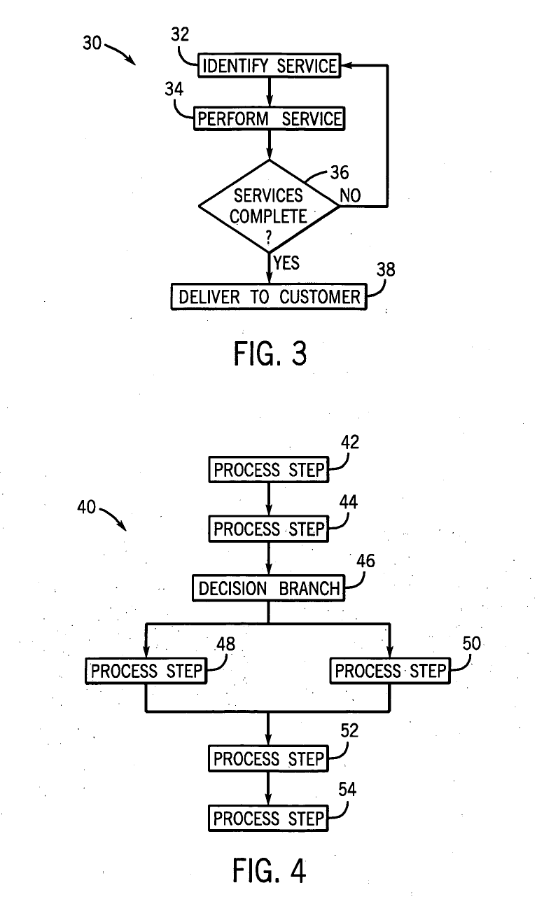

A similar concept applies to the services industry as shown in FIG. 3. In step 32, a service is identified. In step 34, the service is performed. If the services are not complete in step 36, the flow returns to step 32 to identify the next service and the process repeats. If the services are complete in step 36, the customer is notified and the package of services are delivered to the customer in step 38.

In each case, commercial process flow involves multiple steps of manufacture, assembly, or performance of a product or service. The commercial process flow may involve one organization, manufacturer, or service provider, or multiple levels of such organizations or providers. In manufacturing the end product for the consumer, multiple organizations can be involved, each providing multiple processing steps. The end product or deliverable from one organization becomes the raw material, components, or starting point used by the next organizations. While the organizations rarely share records or interact at the detailed manufacturing level, the practices of one organization can dramatically effect another organization.

FIG. 4 illustrates the case of multiple process steps in the commercial processing flow 40, which can occur across one organization or across multiple organizations. Processing step 42 is performed, followed by processing step 44. Again, processing steps 42 and 44 can take a variety of forms involved in the manufacture and assembly, or performance of the respective product or service. The processing flow may include alternative processing steps. Decision branch 46 is used to decide whether a particular product goes to processing step 48 or to processing step 50. The processing flow reconverges to processing steps 52 and 54 to complete the end product.

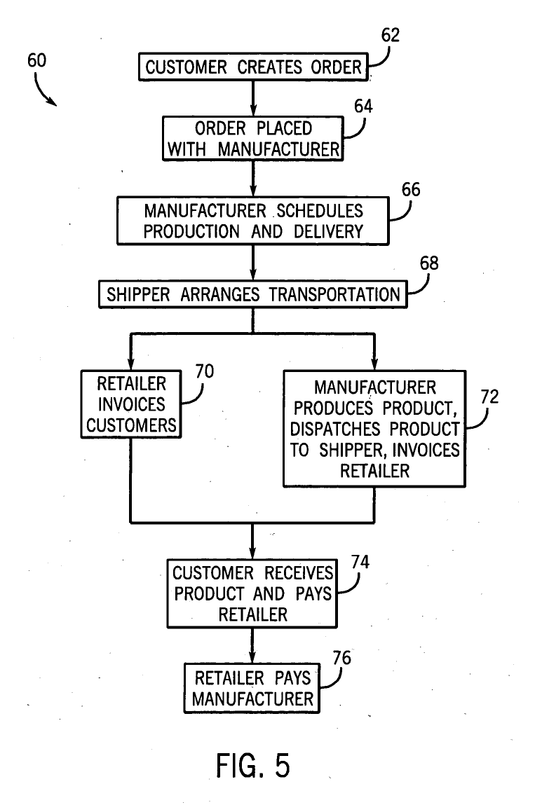

Consider a more specific example of a multi-level processing flow 60 as shown in FIG. 5. In this case, the processing flow involves ordering a new automobile. In step 62, a customer creates an order for a product, i.e., the new auto, from a retailer, i.e., the dealership. In step 64, the order is placed with the manufacturer, i.e., the auto factory. In step 66, the manufacturer schedules production and delivery. In step 68, the shipper arranges for transportation of the product back to the retailer for delivery to the customer.

In the case of special orders, the retailer may invoice the customer in step 70. In a parallel process, the manufacturer produces the product, dispatches the product to the shipper and invoices the retailer in step 72. The process reconverges in step 74 where the customer receives the product and pays the retailer. In step 76, the retailer pays the manufacturer. Each of the above steps are described for simplicity. It is understood that each of the steps of processing flow 60 can be further divided into multiple steps within each processing step. For example, the manufacture of the product in step 72 usually involves many processing steps, with multiple providers, as described for FIGS. 1 and 2.

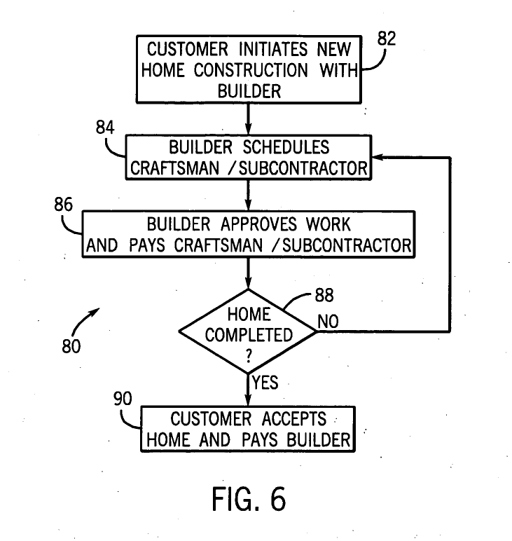

Another example is given in FIG. 6 as processing flow 80. In this case, the processing flow involves construction of a home. In step 82, a customer initiates a new home construction with a builder. In step 84, the builder schedules the various craftsmen and subcontractors to do the work. The land is prepared, the foundation is laid, the framing is done, the roof is installed, exterior walls are put up, and the inside is finished. The inside work involves plumbing, electrical, drywall, cabinetry, flooring, painting, and heating and air conditioning. The landscaper creates the outside decor. In step 86, the builder approves the work and pays the craftsman and contractors. If the home is not complete, step 88 returns to step 84. If the home is complete, the customer accepts the home and pays the builder in step 90. Again, each of the above steps are described for simplicity and it is understood that processing flow 80 can be further divided into multiple steps within each processing step. Each craftsman or subcontractor will perform multiple steps within each task such as described in FIG. 3.

Organizations and people involved in multi-tiered commercial process flows are well aware of the problems that can arise if a defect occurs anywhere in the process. A defect occurs when the process steps are done incorrectly, incompletely, or with faulty materials. The defect may result from incorrect or incomplete documentation, or failure to ship the end product on time, to the proper destination, under the proper shipping conditions. Such latent defects have a significant impact on organizations further downstream, create liability issues, weigh heavily on manufacturers reputations, and reduce consumer confidence.

The present invention involves a process wherein organizations can jointly participate in the design, development, engineering and/or exchange of digital work products according to planned and agreed upon paths and patterns of exchange, i.e., workflows, can log their contributions to work products, as well as prior versions of work products on their computing systems or at a third party logging service provider. In the case of failure of any one of the organization's computing systems engaged in that exchange, or the communication links involved in the exchange, then the most recent version of the work products can be searched for, and rework can ensue from that point forward with confidence that the work product to date has been correctly saved in its appropriate and most complete state by all organizations involved. The embodiment of the process could be in the form of web services, general software or even computing hardware. Typical uses include digital supply chain management, collaborative inter-organizational design, collaborative authoring involving multiple entities, etc. The commercial processing steps include checkpoints for identifying attributes of the process and work completed to the checkpoint so that the appropriate rework can be initiated in the event of a fault or failure. In the event of a fault or failure, the latest recoverable checkpoint can be identified and used as a starting point for the rework.

Organizations engaged in inter-organizational relationships can contractually agree to responsibilities for maintaining work product backups so that those work products can be most efficiently searched for and recovered in the case of failure; participating organizations can use the approach to seamlessly integrate their heterogeneous computing infrastructures using pre-agreed upon standards for deploying web services; there can be public and private portions of the digital work products that are exchanged such that each participating organization can use what they need from the work product to deliver their contribution to that work product, and then pass the work product along to the next organization in the workflow. Fault tolerance and reliability become more critical as organizations continue to increase reliance on partnering organizations.

The present invention provides fault detection and recovery processes in software or hardware for handling the logging of efforts of participants in inter-organizational workflow systems such that if breakdown or failure occurs, the state of work products completed at the time of breakdown can be recovered to their fullest and most complete state possible.

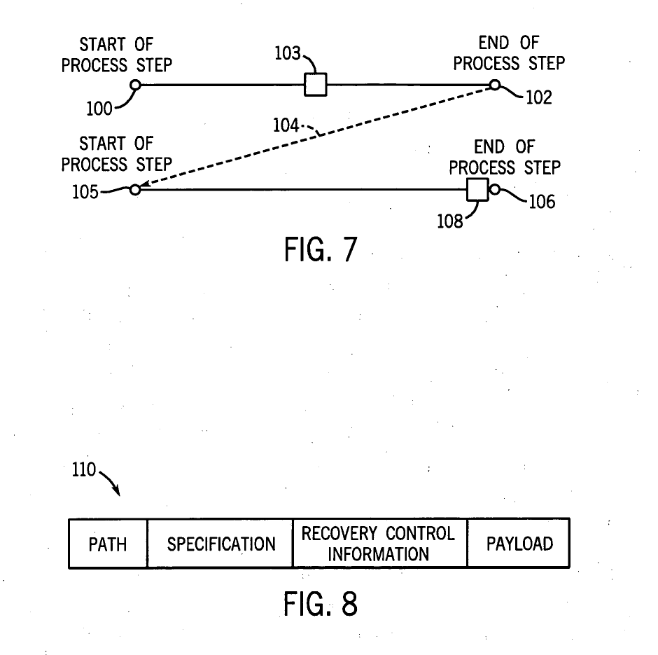

Turning to FIG. 7, further detail of a processing step is shown. The processing step can occur anywhere in the commercial processing flow. Each process step will have a starting point, procedures or actions which occur during and as a result of the processing step, and an ending point. The ending point of one processing step is typically the starting point for the next processing step, which may be within the same organization or as part of the next organization in the flow.

In FIG. 7, point 100 designates the start point of current processing step. The processing step may for example be step 62 in commercial processing flow 60. Certain actions occur during the processing step, e.g., the customer selects style, color, and options for new automobile. Point 102 designates the endpoint of the current processing step, e.g., customer has finished creating the order. At some point between point 100 and 102, depending on the actions being taken during the processing step, a checkpoint 103 is defined for the processing step. The checkpoint 103 may be located at any logical point along the processing step that defines a milestone or well-defined demarcation of the actions taken within the processing step. In many cases, a processing step will comprise multiple actions, tasks, sub-processes, or sub-tasks, performed or taken within the processing step, according to the application or attributes of the process. Any logical endpoint to any task within the processing step can be a checkpoint. In other words, the location of checkpoint 103 is selected as a point within the processing step where the actions taken up to that point or the status of the process can be defined and recorded. In the above case of step 62, checkpoint 103 may be selected the point where the customer has settled on the specifications and options of the new vehicle. In another case from the home construction example, the processing step may be the house plumbing and checkpoint 103 may be defined as the point when the plumbing fixtures and locations have been selected. Again, checkpoint 103 can be defined at any point between the start point and endpoint of the processing step, which provides meaningful recordable data regarding the status of the process to that point. As such, the checkpoint defines a logical recovery point for the commercial processing system in the event of a failure further down the line. Should the commercial processing system fail some where downstream, the completion and recordation of checkpoint 103 gives the system a returning point to start the rework. The completion and recordation of the checkpoint provides a well-defined point where the system can return to re-start at a known good processing point.

From endpoint 102, a message 104 is sent to the start point 105 of the next processing step in the commercial processing flow. The message containing information about the prior processing step is relative to the next processing step. In step 62, message 104 may contain the customer's complete order for the new vehicle. Again, this processing step will have a starting point, procedures or actions which occur during and as a result of the processing step, and an ending point. The ending point of one processing step is typically the starting point for the next processing step, which may be within the same organization or as part of the next organization in the flow.

Starting point 105 may be the start of step 64 of commercial processing flow 60. Again, certain actions occur during the processing step, e.g., customer order is forwarded to the manufacturer. Point 106 designates the end of the processing step. A some point between point 105 and 106, depending on the actions being taken during the processing step, a checkpoint 108 is defined for the processing step. The checkpoint 108 may be located at any point along the processing step. The location of checkpoint 108 is selected as a point where the status of the process can accurately defined and recorded. In this case, checkpoint 108 is placed at the end of the processing step, which provides meaningful recordable data regarding the status of the process to that point.

A checkpoint provides a way of recording or logging data related to the processing step to a central or distributed computer system. By storing the recorded communications from the checkpoints of the commercial processing system in a central or distributed computer system, the last known good state of the process flow and optimal recovery process is available to all organizations involved in the commercial process flow. A processing step may have more than one checkpoint depending on its complexity and importance to the system as a whole. Certain processing steps may not have any checkpoints. The checkpoints are designed to convey meaningful status information to the central computer system to record the present state of the process to that point, including information about the process, and convey such information, as well as recovery procedures, to all organizations involved in the process.

One embodiment of the information content or format of the checkpoint communication is shown in FIG. 8. Communication structure 110 represents the communication link between the checkpoint and the computer system. Communication structure 110 contains a path field, specification field, recovery control field, and payload field. The path field contains information about the path along which the unit of work needs to move as associated with the process flow. The path field may contain node identification, workflow identifier, etc.

The specification field contains information specific to the task and node where the task is executed, especially those elements necessary to communicate the information needed as per the workflow domain. The information may include different permissions for nodes regarding appropriate views of the work in progress. The specification could also contain parameters indicating encryption methods, contractual requirements, control information, and other domain aspects.

The recovery control field contains actions to be taken in recovery mode, i.e., upon detecting or sensing a defect. The actions include such things that are related to the application or domain of the process. In some cases, the state of a fault may have been detected, but the nature of the defect may be unknown. The recovery mode may involve searching for the nature and extent of the failure. The nature of the defect may be determined from a search of the prior processing steps, or the prior processing steps may provide guidance as to where to look for the defect. The recovery information may include a process step or node to return upon fault detection as well as special instructions for the rework. Some defects may require the process to return to different processing steps depending on the nature of the fault and degree of rework necessary to return the system to error-free status. The instruction for the rework helps the operator identify the nature of the fault and most effective and efficient way to fix the problem.

The payload field describes the actual work done so far, or is being done, within the processing step. The payload increases as the product moves through the process. As the nodes complete the necessary operations in accordance with their roles in the workflow, a more refined unit of work passes to the next node or processing step.

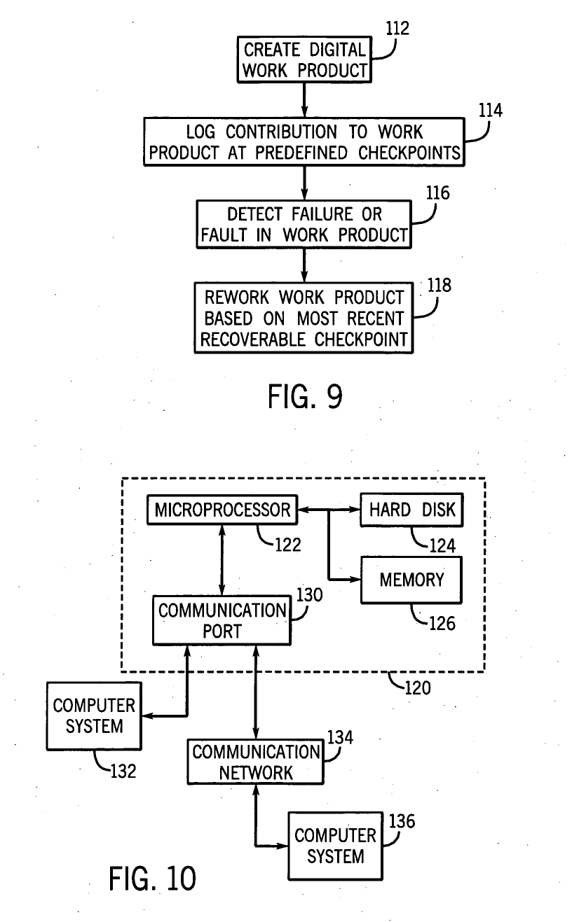

FIG. 9 describes another embodiment of commercial processing flow. In step 112, a digital work product is created. The digital work product is the information related to the process flow which can be readily stored on a computer system. The digital work product can be orders, designs, specifications, instructions, contracts, shipping documents, compliant certificates, and the like. In step 114, the digital work product is part of the information that is logged into the computer system at the checkpoints, as described above. In step 116, a failure in the system is detected. The failure will cause the computer system to return the work flow back to the last known complete step in the process for rework. The nature of the failure and prior recorded checkpoints provide the framework to determine which step the process should return for the rework. In step 118, the rework is performed on the product based on the most recent recoverable checkpoint.

A computer system 120 is shown in FIG. 10 for recording the checkpoint communication in a database. The inter-step messages 104 may also be transmitted to and stored in the database. Computer system 120 includes a central processing unit or microprocessor 122, hard disk or mass storage device 124, and electronic memory 126. The database containing the checkpoint information is stored on hard disk 124. Computer 120 further includes communication port 130 for communicating directly with computer system 132, or through a communication network 134, such as the public Internet, to other computer systems like 136. A communication link from the checkpoint through communication port 130 transmits the checkpoint communication 110 and logs it into the database on hard disk 124. The software and computer programs running on computer 120 perform checkpoint communication logging, fault detection, and fault, failure, and error recovery.

Accordingly, an organization can input checkpoint data via computer 132 into the database of computer 120. Multiple organizations can input data by way of computers like 136 through the Internet in communication network 134. When a product passes through the commercial processing flow, including checkpoints 103 and 108, the checkpoint information set is sent by way of the communication link to the database on computer 120. The database stores processing data for each phase of the commercial processing flow, for use by multiple organizations.

In some situations, a failure can occur in the process flow. The failure can be detected by pulse, pull, push or broadcast protocols. The failure may also be detected by visual inspection, failing quality assurance tests, timeouts, and delays. In the event of a failure, the database on hard disk 124 is queried or searched to determine the last recorded and recoverable checkpoint. Depending on the nature of the failure, the organization(s) can begin the rework process at the last known good recorded checkpoint to correct the defect.

For example, assume from step 62 that the customer has created an order for the new car. Further assume in step 72 that the manufacturer detects a defect in the order, say because the requested options don't match or are not available. Upon detecting the defect, the software on computer system 120 determines that the commercial process needs to return to step 62 to rework the customer's order. The recovery information is derived from the checkpoint communication recorded from the checkpoint in step 62, and possibly other checkpoints from prior processing steps. The computer system known, based on the fault, that rework needs to be done at the last known good processing point, i.e., the starting point 100 of step 62 or to the checkpoint of the prior error-free processing step. The customer clarifies or changes the order and the commercial process continues. Again, the recovery information from computer 120 can be provided across organizational boundaries to increase the efficiency of the rework process.

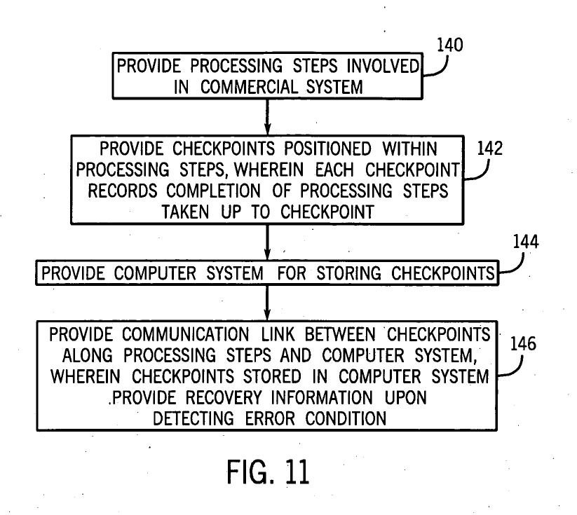

The steps of fault detection and error recovery in a commercial processing system is shown in FIG. 11. Step 140 provides a plurality of processing steps involved in the commercial system which define a product or service. Each of the plurality of processing steps has a start point and an endpoint. Step 142 provides one or more checkpoints positioned between the start point and endpoint of the plurality of processing steps. Each checkpoint provides a communication to record completion of actions taken up to the checkpoint. The checkpoint communication includes a fault recovery field. Step 144 provides a computer system for storing the checkpoint communications. Step 146 provides a communication link between the checkpoints along the plurality of processing steps and the computer system. The communication link is routed through a communication network. The plurality of checkpoints stored in the computer system to provide recovery information upon detecting an error condition.

While one or more embodiments of the present invention have been illustrated in detail, the skilled artisan will appreciate that modifications and adaptations to those embodiments may be made without departing from the scope of the present invention as set forth in the following claims.

1. A commercial system having fault detection and recovery capability, comprising:
a plurality of processing steps involved in the commercial system;
one or more checkpoints positioned within the plurality of processing steps, wherein each checkpoint provides communications to record completion of actions taken up to the checkpoint;
a computer system for storing the communications; and
a communication link between the checkpoints along the plurality of processing steps and the computer system, wherein the communications provide recovery information upon detecting an error condition.

2. The commercial system of claim 1, wherein the plurality of processing steps define a product or service.

3. The commercial system of claim 1, wherein one of the plurality of processing steps has a start point and an endpoint.

4. The commercial system of claim 3, wherein the checkpoint is located between the start point and the endpoint of the processing step.

5. The commercial system of claim 1, wherein the checkpoint defines a recoverable processing point.

6. The commercial system of claim 1, wherein the communications includes a fault recovery field.

7. The commercial system of claim 6, wherein the communications includes a specification field and a payload field.

8. The commercial system of claim 1, wherein the communication link is routed through a communication network.

9. The commercial system of claim 8, wherein the communication network is the public Internet.

10. A method of fault detection and recovery in a commercial system, comprising:
providing a plurality of processing steps involved in the commercial system;
providing a checkpoint within the plurality of processing steps, wherein the checkpoint provides a communication to record completion of actions taken up to the checkpoint; and
recording the communication to provide recovery information upon detecting an error condition.

11. The method of claim 10, further including providing a computer system for storing the communication from the checkpoint.

12. The method of claim 10, wherein the plurality of processing steps define a product or service.

13. The method of claim 10, wherein one of the plurality of processing steps has a start point and an endpoint.

14. The method of claim 13, wherein the checkpoint is located between the start point and the endpoint of the processing step.

15. The method of claim 10, wherein the checkpoint defines a recoverable processing point.

16. The method of claim 10, wherein the communication includes a fault recovery field.

17. The method of claim 16, wherein the communication includes a specification field and a payload field.

18. The method of claim 10, wherein the communication from the checkpoint is routed through a communication network.

19. A method of recovering a commercial process flow, comprising:
providing a processing step involved in the commercial process flow;
providing a checkpoint within the processing step of the commercial process flow; and
recording a communication from the checkpoint for providing recovery information upon detecting an error condition.

20. The method of claim 19, further including providing a computer system for storing the communication from the checkpoint.

21. The method of claim 19, wherein the commercial process flow includes a plurality of processing steps across multiple organizations.

22. The method of claim 19, wherein the processing step has a start point and an endpoint.

23. The method of claim 22, wherein the checkpoint is located between the start point and the endpoint of the processing step.

24. The method of claim 19, wherein the communication includes a fault recovery field.

25. A computer system for fault detection and recovery in a commercial system, comprising:
means for providing a plurality of processing steps involved in the commercial system;
means for providing a checkpoint within the plurality of processing steps, wherein the checkpoint provides a communication to record completion of actions taken up to the checkpoint; and
means for recording the communication for providing recovery information upon detecting an error condition.

26. The computer system of claim 25, wherein one of the plurality of processing steps has a start point and an endpoint.

27. The computer system of claim 26, wherein the checkpoint is located between the start point and the endpoint of the processing step.

28. The computer system of claim 25, wherein the communication includes a fault recovery field.

29. The computer system of claim 28, wherein the communication is routed through a communication network.
